(19) United States
(12) Patent Application Publication
(10) Pub. No.: US 2008/0180985 A1
(43) Pub. Date: Jul. 31, 2008

(54) FERROELECTRIC MEDIA STRUCTURE FOR FERROELECTRIC HARD DISC DRIVE AND METHOD OF FABRICATING THE SAME

(75) Inventors: Yong Kwan KIM, Yongin-si (KR); Seung Bum Hong, Seongnam-si (KR); Ju Hwan Jung, Seoul (KR)

Correspondence Address: SUGHRUE MION, PLLC, 2100 PENNSYLVANIA AVENUE, N.W., SUITE 800, WASHINGTON, DC, 20037, US

(73) Assignee: Samsung Electronics Co., Ltd., Suwon-si (KR)

(21) Appl. No.: 12/021,390

(22) Filed: Jan. 29, 2008

(30) Foreign Application Priority Data
Jan. 29, 2007 (KR) 10-2007-0009122

(51) Int. Cl. G11C 11/22; H01L 21/02

(52) U.S. Cl. 365/145; 438/3; 257/E21.002

(57) ABSTRACT

A recording medium structure for a ferroelectric hard disc drive (HDD) and a method of fabricating the same are provided. A ferroelectric medium is deposited on a glass substrate so as to form a film with a uniform roughness, thereby improving data recording density and reducing the manufacturing costs of such a media structure. In addition, it is possible to remove a process problem occurring when a silicon substrate is employed. The method of fabricating a media structure comprises steps of (a) forming a nucleation template layer on a glass substrate; (b) forming a conductive layer on the nucleation template layer; (c) forming a ferroelectric layer on the conductive layer; and (d) forming a diamond-like carbon (DLC) layer and a lubricant layer in sequence on the ferroelectric layer.

### CROSS-REFERENCE TO RELATED APPLICATIONS

This application claims priority under 35 U.S.C. §119 from Korean Patent Application No. 10-2007-0009122, filed on Jan. 29, 2007, in the Korean Intellectual Property Office, the disclosure of which is incorporated herein by reference in its entirety.

### BACKGROUND OF THE INVENTION

1. Field of the Invention

The present invention relates to a ferroelectric medium structure for a ferroelectric hard disc drive (HDD) and a method of fabricating the same. In particular, the present invention relates to a ferroelectric media structure for a ferroelectric HDD, which is formed by depositing ferroelectric media on a glass substrate so as to form a film with a uniform surface roughness on the glass substrate, thereby increasing data recording density, and a method of fabricating such a ferroelectric media structure.

2. Description of the Prior Art

In general, a hard disk drive (or hard drive or hard disk) is a non-volatile storage device which stores digitally encoded data on rapidly rotating platters with magnetic surfaces. HDDs, which have already formed a market, are implemented as a data storage technology, and from the history of scores of years, it can be said that the drive mechanisms for HDDs are implemented as the most improved technology among mechanically operating devices. The recording density of such HDD products was increased by 100% every year till the year 2002. However, from the year 2003, the annual increase rate of recording density is on a slowdown trend to 28%.

PMR (Perpendicular Magnetic Recording) media have been developed as a high density recording medium, but it is reported that a maximum recording density which can be achieved by PMR media does not exceed about 500 Gb/in². Research for next generation technologies to expand this recording density limit is performed centering around patterned multimedia, HAMR (Heat-Assisted Magnetic Recording), and probes.

Among them, the development of probes based on data storage was initiated so as to fulfill the need for a small high capacity storage device. The Millipede developed by IBM stores data in a storage medium, which is a thin organic film formed on a silicon table or carrier. An array of several thousands of probes is brought into contact with the storage medium and the medium is moved linearly below the probes for writing and reading. In millipede, each of the probes of the array serves as a head. Therefore, millipede uses many nanoscopic heads that can read and write in parallel, thereby can significantly increase the throughput. However, there is a difficulty in that it is necessary to independently apply a writing signal to each of the several thousands of probe heads when writing data, and to independently process a signal emitting from each of the probes when reading data. One solution to overcome this problem is a ferroelectric HDD concept, which is a combination of an HDD drive mechanism and a ferroelectric storage medium. For this purpose, it is essential to secure a method of manufacturing a ferroelectric media structure.

Ferroelectric storage medium structures are generally classified into three types as shown in FIGS. 1A to 1C. FIG. 1 shows an example of ferroelectric medium structure employing a silicon (Si) substrate. FIG. 1A illustrates ferroelectric media structure using a silicon substrate, which includes a silicon oxide film 2, a nucleation template 3, a conductive layer 4, a ferroelectric layer 13 sequentially formed on a silicon substrate 1. FIG. 1B illustrates ferroelectric media structure using a mono-crystalline substrate, which includes a conductive layer 12 and a ferroelectric layer 13 sequentially formed on a mono-crystalline substrate 11. FIG. 1C illustrates ferroelectric media structure using a glass substrate 21, which includes a nucleation template 22, a conductive layer 23, a ferroelectric layer 24 sequentially formed on a glass substrate 21. In FIG. 1A, a multi-layered structure is required so as to provide a ferroelectric layer as a media, and a laser processing step or a dry etching step should be added so as to use the multi-layered structure as an HDD media. As a result, the manufacturing costs increase, thereby deteriorating price competitiveness. If a monocrystalline substrate is employed (FIG. 1B), price competitiveness is also deteriorated because the physical property area of a ferroelectric layer should be increased and the price of such a monocrystalline substrate is high. However, if a glass substrate is employed (FIG. 1C), it is possible to obtain a medium with price competitiveness.

There was reported a polycrystalline lead zirconate titanate (PZT) film formed on Pt/Ti/Coming glass substrates by RF magnetron sputtering using a Pb(Zr_{0.5}, Ti_{0.5})O₃ ceramic target. (Thomas et al., Jpn. J. Appl. Phys. Vol. 40 (2001) pp. 5511-5517). However, such a prior research is merely a basic research performed in terms of a macroscopic physical property in the polycrystalline film Therefore, the prior research has nothing to do with a thin film structure with a preferred orientation for maximizing the physical properties concerned with a micro-ferroelectric domain size and a surface potential, and a method of fabricating such a film structure.

### SUMMARY OF THE INVENTION

The present invention provides a ferroelectric storage medium structure for a novel ferroelectric hard disc drive (HDD), which can improve the price competitiveness of a drive mechanism of such an HDD and a ferroelectric medium, and a method of fabricating such a ferroelectric medium structure.

In addition, the present invention provides a ferroelectric storage medium structure for a ferroelectric HDD and a method of fabricating the same, wherein a ferroelectric medium is deposited on a glass substrate, so that a uniform film can be formed on the substrate and data recording density can be increased.

Furthermore, the present invention provides a ferroelectric storage medium structure for a ferroelectric HDD and a method of fabricating the same, which can reduce the manufacturing costs.

According to an aspect of the present invention, there is provided a method of fabricating a ferroelectric storage medium suitable for a ferroelectric hard disc drive (HDD), including steps of: (a) forming a nucleation template layer on a glass substrate; (b) forming a conductive layer on the nucleation template layer; (c) forming a ferroelectric layer on the conductive layer; and (d) forming a diamond-like carbon (DLC) layer and a lubricant layer in sequence on the ferroelectric layer.

According to another aspect of the present invention, there is provided a method of fabricating a ferroelectric storage media for a ferroelectric hard disc drive (HDD) including steps of: (a) forming a conductive layer on a glass substrate; (b) forming a ferroelectric layer on the conductive layer; and (c) forming a diamond-like carbon (DLC) layer and a lubricant layer in sequence on the ferroelectric layer.

The nucleation template layer may be formed by using any one selected from a group consisting of a tantalum (Ta) template, a zirconium (Zr) template, and a chromium (Cr) template.

The nucleation template layer may be formed by a conventional deposition using any conventional deposition equipment, such as sputtering equipment, at room temperature.

The nucleation template layer may be deposited using a high frequency power source of not more than 100 W, within a 100% argon (Ar) atmosphere at a pressure of about 1 to 20 mTorr.

The nucleation template layer may be formed in a thickness of not more than 10 nm.

The conductive layer may be formed using a conductive material such as platinum (Pt).

The conductive layer may be deposited at a temperature of about 300° C. to about 500° C. using any conventional deposition equipment, such as sputtering equipment.

The conductive layer may be formed using a high frequency power source of not more than 50 W, within a 100% Argon (Ar) atmosphere of about 1 to 20 mTorr.

The conductive layer may be formed in a thickness of about 10 nm to 100 nm.

The ferroelectric layer may be formed using any one ferroelectric substance selected from PbTiO₃, lead zirconate titanate (PZT), lanthanum-modified lead titanate (PLT), bismuth lead titanate (BLT), barium strontium titanate (BST), and strontium bismuth titanate (SBT).

The ferroelectric layer may be deposited at a temperature of about 450° C. to about 650° C. using any conventional deposition equipment, such as pulsed laser deposition equipment.

The conductive layer may be formed using a high frequency power source of not more than 50 W, within a 100% Oxygen (O₂) atmosphere of about 10 to 200 mTorr.

The ferroelectric layer may be formed in a thickness of not more than 50 nm.

According to another aspect of the present invention, there is provided a ferromagnetic storage medium structure for a hard disc drive (HDD) including: a glass substrate; a nucleation template layer formed on the glass substrate; a conductive layer formed on the nucleation template layer; a ferroelectric layer formed on the conductive layer; a diamond-like carbon (DLC) layer formed on the ferroelectric layer, and a lubricant layer formed on the DLC layer.

In addition, according to another aspect of the present invention, there is provided a ferromagnetic storage medium structure for a hard disc drive (HDD) including: a glass substrate; a conductive layer formed on a glass substrate; a ferroelectric layer formed on the conductive layer; and a diamond-like carbon (DLC) layer and a lubricant layer sequentially formed on the ferroelectric layer.

The nucleation template layer may be formed of any one selected from a group consisting of a tantalum (Ta) template, a zirconium (Zr) template, and a chromium (Cr) template.

The nucleation template layer may have a thickness of not more than 10 nm.

The conductive layer may be formed using a conductive material such as platinum (Pt).

The conductive layer may have a thickness of about 10 nm to about 100 nm.

The ferroelectric layer may be formed using any one ferroelectric substance selected from PbTiO₃, lead zirconate titanate (PZT), lanthanum-modified lead titanate (PLT), bismuth lead titanate (BLT), barium strontium titanate (BST), and strontium bismuth titanate (SBT).

The ferroelectric layer may have a thickness of not more than 50 nm.

In another embodiment of the present invention, there is provided a data storage system including (a) a storage medium containing a glass substrate; a conductive layer formed on the glass substrate; a ferroelectric layer formed on the conductive layer; a diamond-like carbon (DLC) layer formed on the ferroelectric layer; and a lubricant layer formed on the DLC layer; (b) a write head comprising an electrically conducting member comprising a projecting portion (“tip”); (c) a read head comprising a field effect transistor; and (d) a drive adapted to move the storage medium laterally.

The storage medium of the data storage system may further include a nucleation template layer interposed the glass substrate and the conductive layer.

### BRIEF DESCRIPTION OF THE DRAWINGS

The above and other objects, features and advantages of the present invention will be more apparent from the following detailed description taken in conjunction with the accompanying drawings, in which:

FIGS. 1A to 1C show conventional ferroelectric medium structures, in which FIG. 1A shows a ferroelectric medium structure employing a silicon substrate, FIG. 1B is a ferroelectric medium structure employing a monocrystalline substrate, and FIG. 1C is a ferroelectric medium structure employing a glass substrate;

FIGS. 2A to 2E show a method of fabricating a ferroelectric medium for a ferroelectric HDD according to a first embodiment of the present invention;

FIG. 3 is a flowchart showing the method of fabricating the ferroelectric medium for a ferroelectric HDD according to the first embodiment of the present invention;

FIGS. 4A to 4D show a method of fabricating a ferroelectric medium for a ferroelectric HDD according to a second embodiment of the present invention step;

FIG. 5 is a flowchart showing the method of fabricating the ferroelectric medium for a ferroelectric HDD according to the second embodiment of the present invention;

FIG. 6 shows parts of a HDD data storage system including a ferromagnetic storage medium, a read/write head, and an actuator arm of a drive;

FIG. 7A shows an X-ray diffraction pattern of a ferroelectric media structure formed by a glass substrate/ a nucleation template (Ta)/ a conductive layer (Pt)/ a ferroelectric layer (PbTiO₃) according to the first embodiment of the present invention;

FIG. 7B shows an X-ray diffraction pattern of a ferroelectric media structure formed by a glass substrate/ a conductive layer (Pt)/ a ferroelectric layer (PbTiO₃) according to the second embodiment of the present invention; and

FIGS. 8 to 10 show enlarged photographs showing the PFM results and line profiles of a ferroelectric layer (PbTiO₃) grown on a template (Ta) coated glass substrate.

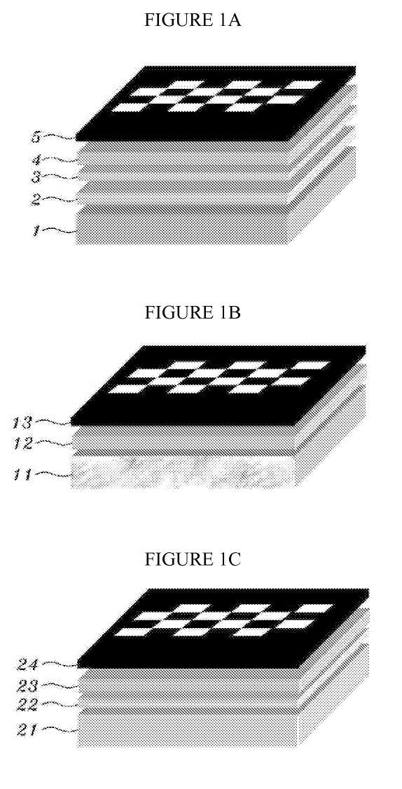

### DETAILED DESCRIPTION OF THE EXEMPLARY EMBODIMENTS

Hereinafter, exemplary embodiments of the present invention will be described with reference to the accompanying drawings. It should be noted that the figures in the accompanying drawings are exaggerated in size for the convenience of description.

### First Embodiment

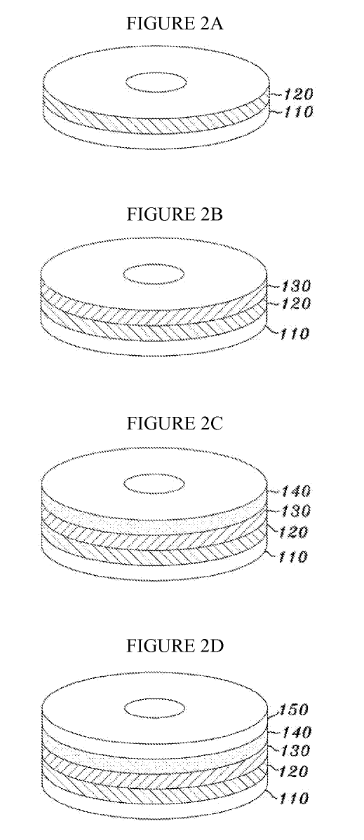

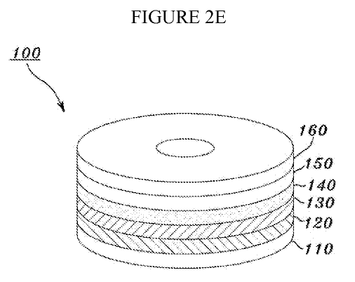

FIGS. 2A to 2E show a method of fabricating a ferroelectric medium for a ferroelectric HDD according to a first embodiment of the present invention, and FIG. 3 is a flowchart showing the method of fabricating the ferroelectric medium for a ferroelectric HDD according to the first embodiment of the present invention.

The present invention realizes a read/write head by using a ferroelectric media deposited as shown in FIG. 2E, so as to employ the head in a ferroelectric HDD.

It is possible to deposit a polycrystalline ferroelectric thin film using a currently reported method. However, it is difficult to form a uniform polycrystalline film having a smooth surface, as required for being used as a head of an HDD. In addition, it is difficult to secure a satisfactory ferroelectric physical property from such a thin film. As a result, it is difficult to obtain a ferroelectric film with high density.

According to an embodiment of the present invention, as shown in FIG. 2A, a nucleation template layer 120 of several nm (nanometers) is formed on a glass substrate 110 at room temperature using any conventional deposition equipment, such as sputtering equipment.

Here, the nucleation template layer 120 is formed, preferably in a thickness of not more than 10 nm using any one selected from a group comprising a tantalum nucleation template, a zirconium nucleation template, and a chromium nucleation template. The deposition of the nucleation template layer 120 may be performed using a high frequency power source of not more than 100 W, within a 100% argon (Ar) atmosphere at a pressure of about 1 to 20 mTorr (Step S100 in FIG. 3).

Next, as shown in FIG. 2B, a preferred oriented conductive layer 130 is formed in a thickness of several tens of nm on the nucleation template layer 120 using any conventional deposition equipment, such as sputtering equipment, at a temperature of about 300 to 500° C.

The preferred oriented conductive layer 130 is deposited in a thickness of about 10 nm to about 100 nm. The conductive layer 130 may be formed of platinum (Pt). At this time, the deposition process is performed using a high frequency power source of 1 to 50 W, within a 100% argon (Ar) atmosphere at a pressure of about 1 to 20 mTorr (Step S110 in FIG. 3).

Then, as shown in FIG. 2C, a preferred oriented ferroelectric layer 140, which has a ferroelectric physical property suitable for use as an HDD media, is deposited on the preferred oriented conductive layer 130 using any conventional deposition equipment, such as pulsed laser deposition equipment, at a high temperature of about 450 to 650° C.

At this time, the preferred oriented ferroelectric layer 140 is formed in a thickness of not more than 50 nm using any one of ferroelectric substances such as PbTiO₃, lead zirconate titanate (PZT), lanthanum-modified lead titanate (PLT), bismuth lead titanate (BLT), barium strontium titanate (BST), and strontium bismuth titanate (SBT). In addition, the deposition process is performed using a high frequency of 1 to 50 W, within a 100% oxygen (O₂) atmosphere at a pressure of about 10 to 200 mTorr (Step S120 in FIG. 3).

Next, as shown in FIGS. 2D and 2E, a diamond-like carbon (DLC) layer 150 and a lubricant layer 160 are sequentially laminated on the preferred oriented ferroelectric layer 140, thereby finishing a ferroelectric media 100 deposited on the glass substrate 110 (Steps S130 to S140 in FIG. 3).

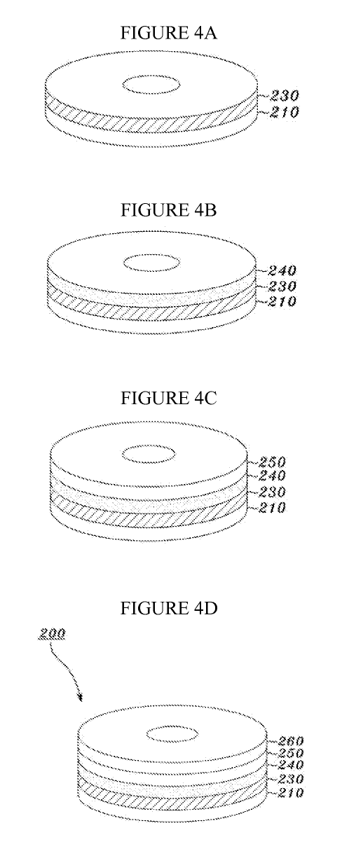

A ferroelectric HDD may be fabricated by combining a read/write head (not shown) with the ferroelectric medium 100 and a HDD driving apparatus using a conventional HDD head fabrication process. For example, FIG. 6 shows parts of an exemplary ferroelectric HDD including a read/write head 310, a ferroelectric medium 100, and an actuator arm of a HDD driving apparatus 300.

As described above, the ferroelectric medium structure for a ferroelectric hard disc drive (HDD) according to the first embodiment of the present invention includes a glass substrate 110, a nucleation template 120 formed on the glass substrate 110, a preferred oriented conductive layer 130 formed on the nucleation template 120, a preferred oriented ferroelectric layer 140 formed on the conductive layer 130, a DLC layer 150 formed on the ferroelectric layer 140 and a lubricant layer 160 formed on the DLC layer 150, as shown in FIG. 2E.

### Second Embodiment

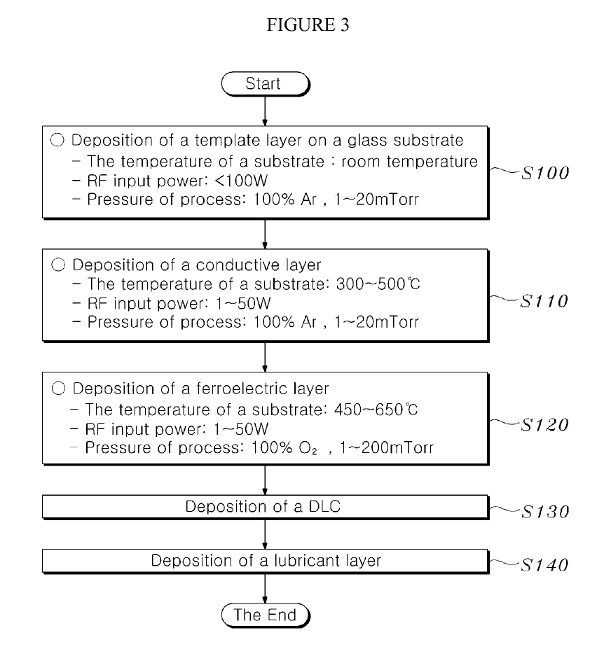

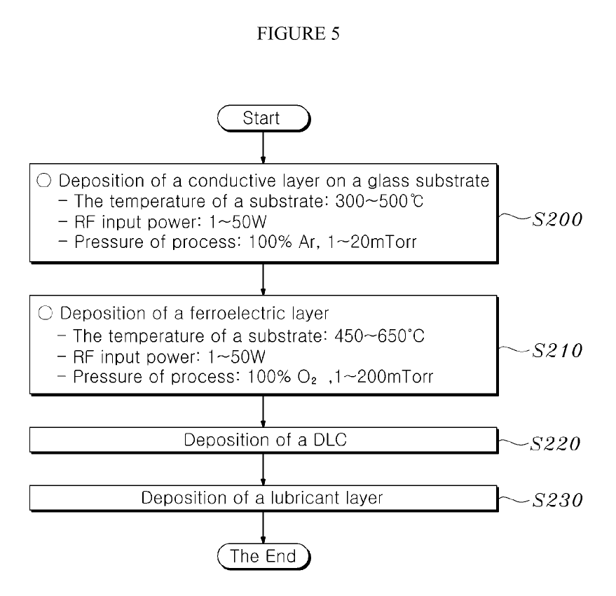

FIGS. 4A to 4D show a method of fabricating a ferroelectric media for a ferroelectric HDD according to a second embodiment of the present invention, and FIG. 5 is a flowchart showing the method of fabricating the ferroelectric media for a ferroelectric HDD according to the second embodiment of the present invention.

At first, a preferred oriented conducive layer 230 is formed in a thickness of several tens of nm on a glass substrate 210 at a temperature of about 300 to 500° C. The formation of conductive layer 230 may be carried out by a known deposition using any conventional equipment such as sputtering equipment, as shown in FIG. 4A.

The preferred oriented conductive layer 230 may be formed of platinum (Pt) in a thickness of 10 nm to 100 nm. At this time, the deposition process is performed using a high frequency power source of 1 to 50 W, within a 100% argon (Ar) atmosphere at a pressure of about 1 to 20 mTorr (Step S200 in FIG. 5).

Next, as shown in FIG. 4B, a preferred oriented ferroelectric layer 240, which has a ferroelectric physical property suitable for use as an HDD medium, is formed on the preferred oriented conductive layer 230 by, for example, a deposition process. The deposition may be performed using any conventional deposition equipment, such as pulsed laser deposition equipment, at a temperature of about 450 to 650° C.

At this time, the preferred oriented ferroelectric layer 240 is formed in a thickness of not more than 50 nm using any one of ferroelectric substances such as PbTiO₃, lead zirconate titanate (PZT), lanthanum-modified lead titanate (PLT), bismuth lead titanate (BLT), barium strontium titanate (BST), and strontium bismuth titanate (SBT). In addition, the deposition process is performed by using a high frequency of 1 to 50 W, within a 100% oxygen (O₂) atmosphere at a pressure of about 10 to 200 mTorr (Step S210 in FIG. 5).

Next, as shown in FIGS. 4C and 4D, a diamond-like carbon (DLC) layer 250 and a lubricant layer 260 are sequentially formed on the preferred oriented ferroelectric layer 240, thereby finishing a ferroelectric medium 200 formed on the glass substrate 210 (Steps S220 to S230 in FIG. 5).

Next, a ferroelectric HDD is fabricated by combining a read/write head with the ferroelectric medium 200 and a HDD driving apparatus using a conventional HDD head fabrication process. FIG. 6 shows parts of an exemplary ferroelectric HDD including a read/write head 310, a ferroelectric medium 200, and a HDD driving apparatus 300.

As described above, the ferroelectric medium structure for a ferroelectric hard disc drive (HDD) according to the second embodiment of the present invention includes a glass substrate 210, a preferred oriented conductive layer 230 formed on a glass substrate 210, a preferred oriented ferroelectric layer 240 formed on the preferred oriented conductive layer 230, a DLC layer 250 formed on the ferroelectric layer and a lubricant layer 260 formed on the DLC layer 250, as shown in FIG. 4E.

FIG. 6 shows an exemplary ferroelectric HDD (or a data storage system) including a ferroelectric medium 100 or 200 formed on a glass substrate (not shown), a read/write head 310, and an HDD driving apparatus 300. The medium is disk shaped and the system may have a driving apparatus' spindle motor affixed to the center of the medium to rotate the medium.

The structure of the ferroelectric medium 100 or 200 can be variously configured according to how to combine a nucleation template layer, a conductive layer, and a ferroelectric layer.

In FIG. 6, the “a” section indicates an area for reading and writing data on the ferroelectric medium 100 or 200 by a read/write head 310, and the “b section” indicates a track taken in order to describe the ferroelectric media 100 or 200. The medium may be rotated in a direction “Q” by the action of the spindle motor 320. The fabrication and mechanical operation of a HDD or data storage system (i.e., a read/write head, actuator arm, or operating motor, etc) are well known in the art and, thus will not be described in detail.

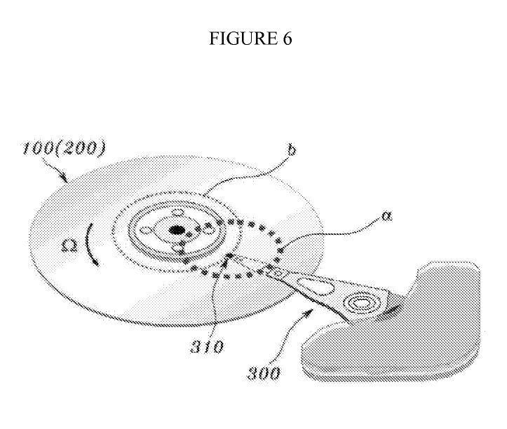

FIG. 7A shows an X-ray diffraction pattern of a ferroelectric medium including a glass substrate/ a nucleation template (Ta)/ a conductive layer (Pt)/ a ferroelectric substance (PbTiO₃) according to the first embodiment of the present invention, and FIG. 7B shows an X-ray diffraction pattern of a ferroelectric medium including a glass substrate/ a conductive layer (Pt)/ a ferroelectric substance (PbTiO₃) according to the second embodiment of the present invention.

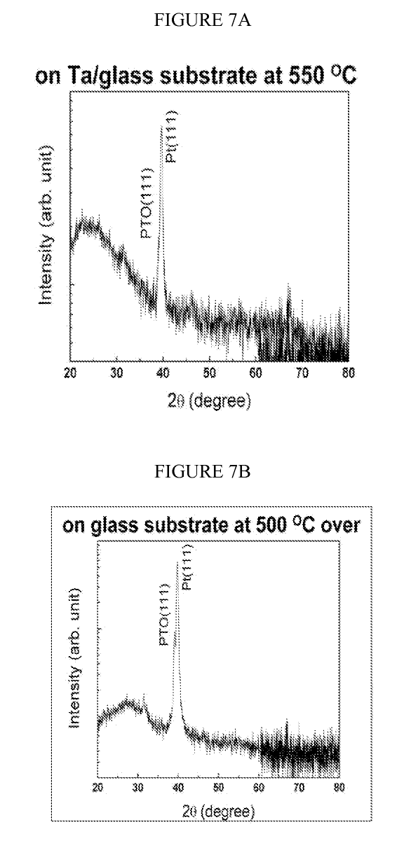

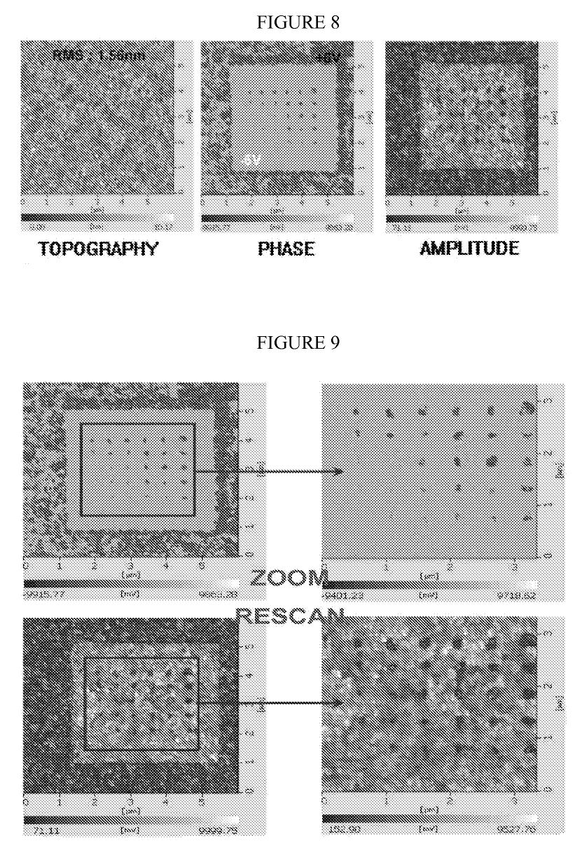

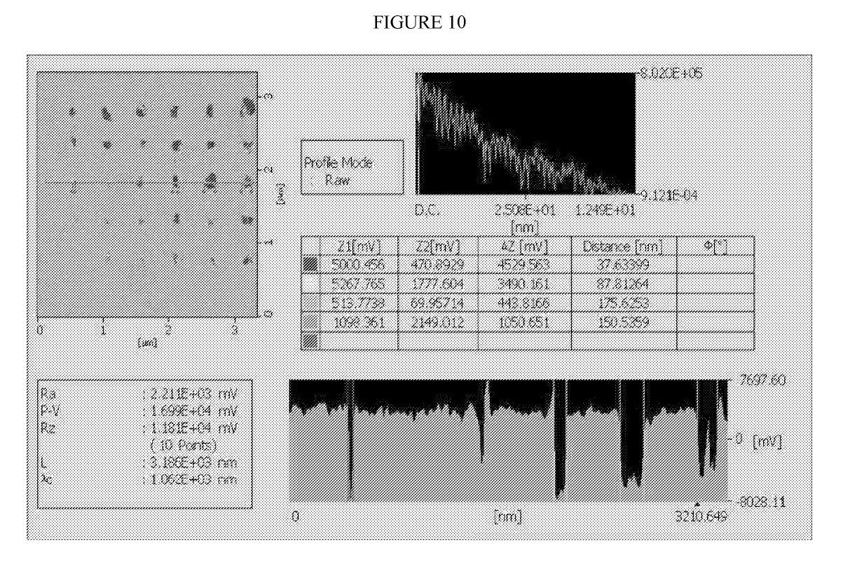

In addition, FIGS. 8 to 10 show enlarged photographs showing the photonic force microscope (PFM) results and line profiles of a ferroelectric layer (PbTiO₃) grown on a glass substrate which is coated with a Ta nucleation template layer, wherein the figures demonstrate that it is possible to read/write on a ferroelectric medium.

As shown in FIG. 7A, by using the above mentioned deposition conditions, a ferroelectric medium (PbTiO₃) with a 111-preferred orientation can be successfully deposited. In addition, as shown in FIGS. 8 to 10, it is possible to obtain a ferroelectric medium which has a uniform surface roughness of 1.56 nm and makes it possible to read/write data at a thickness of several tens of nm (e.g., 30 to 40 nm), whereby the ferroelectric medium reveals a ferroelectric physical property which allows the ferroelectric medium to be used as a ferroelectric HDD medium. Such a medium can increase data recording density.

In addition, because an existing HDD platform can be used without modifications or with insignificant modifications, it is possible to avoid an increase of costs.

Furthermore, because a ferroelectric medium is fabricated using a glass substrate, it is possible to reduce the costs for fabricating such a ferroelectric medium and to avoid disadvantages in association with the use of a silicon substrate.

Although several exemplary embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A method of fabricating a ferroelectric storage medium comprising steps of
(a) forming a conductive layer on a glass substrate;
(b) forming a ferroelectric layer on the conductive layer;
(c) forming a diamond-like carbon (DLC) layer; and
(d) forming a lubricant layer on the DLC layer.

2. A method as claimed in claim 1, which further comprises the step of forming a nucleation template layer on the glass substrate, prior to forming the conductive layer.

3. A method as claimed in claim 2, wherein the nucleation template layer is formed of any one selected from a group consisting of a tantalum (Ta) template, a zirconium (Zr) template, and a chromium (Cr) template.

4. A method as claimed in claim 2, wherein the nucleation template layer is formed by a deposition process at room temperature.

5. A method as claimed in claim 4, wherein the deposition process is a sputtering deposition using a high frequency power source of not more than 100 W, a 100% argon (Ar) atmosphere and a pressure of about 1 to 20 mTorr.

6. A method as claimed in claim 2, wherein the nucleation template layer has a thickness of not more than 10 nm.

7. A method as claimed in claim 1, wherein the conductive layer is formed of platinum (Pt).

8. A method as claimed in claim 1, wherein the conductive layer is formed by a deposition process at a temperature of about 300° C. to 500° C.

9. A method as claimed in claim 8, wherein the deposition is a sputtering deposition using a high frequency power source of not more than 50 W, a 100% Argon (Ar) atmosphere and a pressure of about 1 to 20 mTorr.

10. A method as claimed in claim 1, wherein the conductive layer has a thickness of about 10 nm to 100 nm.

11. A method as claimed in claim 1, wherein the ferroelectric layer is formed of any one ferroelectric substance selected from PbTiO₃, lead zirconate titanate (PZT), lanthanum-modified lead titanate (PLT), bismuth lead titanate (BLT), barium strontium titanate (BST), and strontium bismuth titanate (SBT).

12. A method as claimed in claim 1, wherein the ferroelectric layer is formed by a deposition at a temperature of about 450° C. to about 650° C.

13. A method as claimed in claim 12, wherein the deposition is a pulse laser deposition using a high frequency power source of not more than 50 W and a 100% Oxygen (O₂) atmosphere of about 10 to 200 mTorr.

14. A method as claimed in claim 1, wherein the ferroelectric layer has a thickness of not more than 50 nm.

15. A ferroelectric storage medium structure comprising:
a glass substrate;
a conductive layer formed on the glass substrate;
a ferroelectric layer formed on the conductive layer;
a diamond-like carbon (DLC) layer formed on the ferroelectric layer; and
a lubricant layer formed on the DLC layer.

16. A ferroelectric storage medium structure as claimed in claim 15, which further comprises a nucleation template layer interposed the glass substrate and the conductive layer.

17. A ferroelectric storage medium structure as claimed in claim 16, wherein the nucleation template layer is formed of any one selected from a group consisting of a tantalum (Ta) template, a zirconium (Zr) template, and a chromium (Cr) template.

18. A ferroelectric storage medium structure as claimed in claim 16, wherein the nucleation template layer has a thickness of not more than 10 nm.

19. A ferroelectric storage medium structure as claimed in claim 15, wherein the conductive layer is formed of platinum (Pt).

20. A ferroelectric storage medium structure as claimed in claim 15, wherein the conductive layer has a thickness of about 10 nm to 100 nm.

21. A ferroelectric storage medium structure as claimed in claim 15, wherein the ferroelectric layer is formed of any one ferroelectric substance selected from PbTiO₃, lead zirconate titanate (PZT), lanthanum-modified lead titanate (PLT), bismuth lead titanate (BLT), barium strontium titanate (BST), and strontium bismuth titanate (SBT).

22. A ferroelectric storage medium structure as claimed in claim 15, wherein the ferroelectric layer has a thickness of not more than 50 nm.

23. A data storage system comprising
a) a storage medium comprising a glass substrate; a conductive layer formed on the glass substrate; a ferroelectric layer formed on the conductive layer; a diamond-like carbon (DLC) layer formed on the ferroelectric layer; and a lubricant layer formed on the DLC layer;
b) a write head comprising an electrically conducting member comprising a projecting portion (“tip”);
c) a read head comprising a field effect transistor; and
d) a drive adapted to move the storage medium laterally.

24. A data storage system as claimed in claim 23, wherein the storage medium further comprises a nucleation template layer interposed the glass substrate and the conductive layer.

25. A data storage system as claimed in claim 24, wherein the nucleation template layer is formed of any one selected from a group consisting of a tantalum (Ta) template, a zirconium (Zr) template, and a chromium (Cr) template.

26. A data storage system as claimed in claim 24, wherein the nucleation template layer has a thickness of not more than 10 nm.

27. A data storage system as claimed in claim 23, wherein the conductive layer is formed of platinum (Pt).

28. A data storage system as claimed in claim 23, wherein the conductive layer has a thickness of about 10 nm to 100 nm.

29. A data storage system as claimed in claim 23, wherein the ferroelectric layer is formed of any one ferroelectric substance selected from PbTiO₃, lead zirconate titanate (PZT), lanthanum-modified lead titanate (PLT), bismuth lead titanate (BLT), barium strontium titanate (BST), and strontium bismuth titanate (SBT).

30. A data storage system as claimed in claim 23, wherein the ferroelectric layer has a thickness of not more than 50 nm.
